(19) United States
(12) Patent Application Publication
(10) Pub. No.: US 2025/0255170 A1
(43) Pub. Date: Aug. 7, 2025

(54) DISPLAY DEVICE, METHOD FOR MANUFACTURING THE SAME, AND METHOD FOR REPAIRING THE SAME

(71) Applicant: Samsung Display Co., LTD., Yongin-si (KR)

(72) Inventors: SANGDUK LEE, Yongin-si (KR); HOIKWAN LEE, Yongin-si (KR); Yunyoung LEE, Yongin-si (KR)

(21) Appl. No.: 18/965,110

(22) Filed: Dec. 2, 2024

(30) Foreign Application Priority Data
Feb. 7, 2024 (KR) 10-2024-0018817

(51) Int. Cl. H10K 71/00; H10K 59/80

(52) U.S. Cl. CPC H10K 71/861; H10K 59/8792

(57) ABSTRACT

A method for repairing a display device includes preparing a display device including a display panel, an anti-reflection layer disposed on the display panel, an adhesive layer disposed on the anti-reflection layer, and a window disposed on the adhesive layer, where an edge of the window is disposed outside the display panel when viewed in a thickness direction of the display panel, includes removing the window and the adhesive layer from the display device, providing a new adhesive layer on the anti-reflection layer, and providing a new window on the new adhesive layer. The window is formed by directly coating a first transparent resin on a top surface of the adhesive layer.

This application claims priority to Korean Patent Application No. 10-2024-0018817, filed on Feb. 7, 2024, and all the benefits accruing therefrom under 35 U.S.C. § 119, the content of which in its entirety is herein incorporated by reference.

### BACKGROUND

### (1) Field

Embodiments of the disclosure herein relate to a display device, a method for manufacturing the display device, and a method for repairing the display device.

### (2) Description of the Related Art

In general, an electronic device for providing an image to a user such as smartphones, digital cameras, laptop computers, navigations, smart televisions, and the like typically includes a display device for displaying an image. Such a display device generates an image to provide the generated image to the user through a display screen.

The display device includes a display panel that generates an image and a window disposed on the display panel. The window protects the display panel from external scratches and impacts.

### SUMMARY

If defects occur in a window of a display device, a process of replacing the window may be performed. Accordingly, it may be desired to develop technology for easily removing a defective window from the display device.

The disclosure provide a display device that is easy to be repaired and a method of manufacturing the display device. The disclosure also provide a method for repairing a display device that is easy to be repaired.

In an embodiment of the invention, a method for repairing a display device includes: preparing a display device including a display panel, an anti-reflection layer disposed on the display panel, an adhesive layer disposed on the anti-reflection layer, and a window disposed on the adhesive layer, where an edge of the window is disposed outside the display panel when viewed in a thickness direction of the display panel; removing the window and the adhesive layer from the display device; providing a new adhesive layer on the anti-reflection layer; and providing a new window on the new adhesive layer, where the window is formed by directly coating a first transparent resin on a top surface of the adhesive layer.

In an embodiment of the invention, a display device includes: a display panel; an anti-reflection layer disposed on the display panel; an adhesive layer disposed on the anti-reflection layer; and a window disposed on the adhesive layer, where each of the window, the adhesive layer, and the anti-reflection layer has a width greater than a width of the display panel when viewed in a thickness direction of the display panel, and the window is defined by a transparent resin coating layer which is directly coated on a top surface of the adhesive layer.

In an embodiment of the invention, a method for manufacturing a display device includes: providing an anti-reflection layer on a display panel; providing an adhesive layer on the anti-reflection layer; directly applying a transparent resin on a top surface of the adhesive layer; and curing the transparent resin to form a window, where each of the window, the adhesive layer, and the anti-reflection layer has a width greater than a width of the display panel when viewed in a thickness direction of the display panel.

### BRIEF DESCRIPTION OF THE DRAWINGS

The above and other features of embodiments of the invention will become more apparent by describing in further detail embodiments thereof with reference to the accompanying drawings, in which:

FIG. 1 is a perspective view of a display device according to an embodiment of the invention;

FIG. 2 is a cross-sectional view illustrating an embodiment of the display device illustrated in FIG. 1.

FIG. 3 is a cross-sectional view illustrating an embodiment of a display panel illustrated in FIG. 2.

FIG. 4 is a cross-sectional view illustrating a display panel according to another embodiment of the invention;

FIG. 5 is a plan view of a display panel illustrated in FIG. 2;

FIGS. 6A to 6E are views for explaining a method for manufacturing a display device according to an embodiment of the invention;

FIGS. 7A to 7F are views for explaining a method for repairing the display device according to an embodiment of the invention;

FIGS. 8A to 8D are views for explaining a method for repairing a display device according to another embodiment of the invention;

FIGS. 9A and 9B are views for explaining a process of removing a window of a comparative display device; and

FIGS. 10A to 10E are views for explaining a method for repairing a display device according to another embodiment of the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In this specification, it will also be understood that when one component (or area, layer, portion) is referred to as being “on”, “connected to”, or “coupled to” another component, it can be directly disposed/connected/coupled on/to the one component, or an intervening third component may also be present.

Like reference numerals refer to like elements throughout. Also, in the figures, the thickness, ratio, and dimensions of components are exaggerated for clarity of illustration.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described with reference to the accompanying drawings.

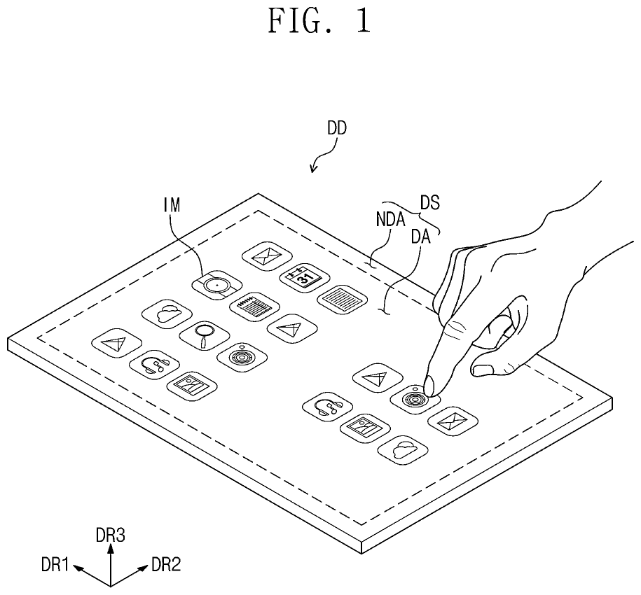

FIG. 1 is a perspective view of a display device according to an embodiment of the invention;

Referring to FIG. 1, a display device DD according to an embodiment of the invention has a rectangular shape having long sides extending in a first direction DR1 and short sides extending in a second direction DR2 crossing the first direction DR1. However, the embodiment of the invention is not limited thereto. For example, the display device DD may have one of other various shapes such as a circular shape or a polygonal shape.

Hereinafter, a direction that substantially perpendicularly crosses a plane defined by the first direction DR1 and the second direction DR2 is defined as a third direction DR3. The third direction DR3 may be a thickness direction of the display device DD. Also, in this specification, the meaning when viewed on a plane is defined as a state viewed in the third direction D3.

A top surface of the display device DD may be defined as a display surface DS and have a plane defined by the first direction DR1 and the second direction DR2. Images IM generated from the display device DD may be provided to a user through the display surface DS.

The display surface DS may include a display area DA and a non-display area NDA around the display area DA. An image may be displayed on the display area DA, but may not be displayed on the non-display area NDA. The non-display area NDA may surround the display area DA and define an edge of the display device DD, which is printed with a predetermined color.

The display device DD may be used for large-sized electronic devices such as televisions, monitors, or external billboards. Also, the electronic device ED may be used for small or medium-sized electronic devices such as personal computers, notebook computers, personal digital assistants, car navigation systems, game consoles, smart phones, tablet computers, and cameras. However, the above-described devices are listed as merely an example, and thus, the display device DD may be adopted for other electronic devices unless departing from the teachings therein.

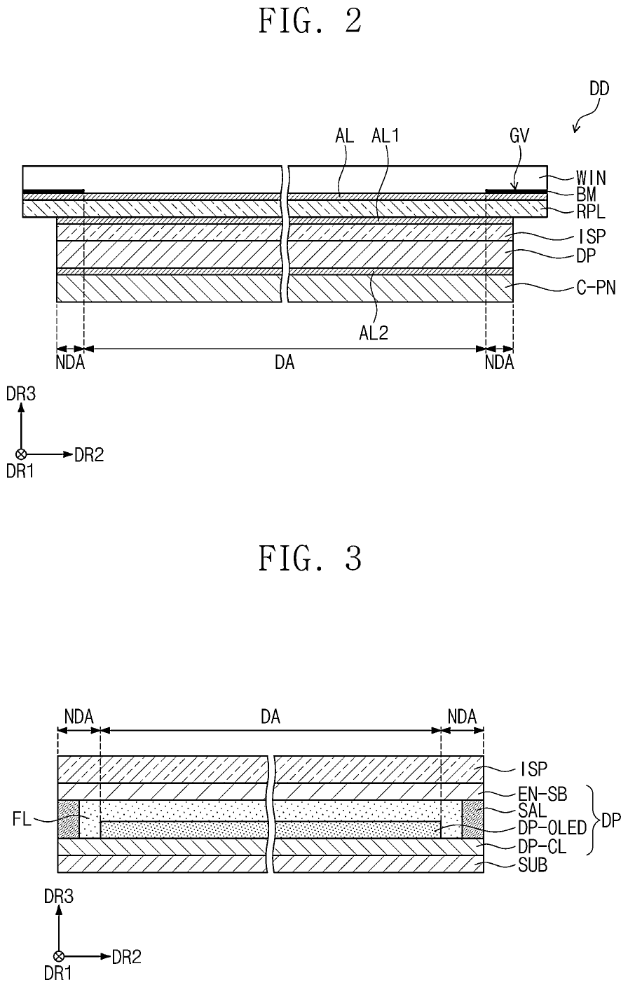

FIG. 2 is a cross-sectional view illustrating an embodiment of the display device illustrated in FIG. 1.

For example, FIG. 2 illustrates a cross-sectional view of an embodiment of the display device DD when viewed in the first direction DR1.

Referring to FIG. 2, an embodiment of the display device DD may include a display panel DP, an input sensing part ISP, an anti-reflection layer RPL, a window WIN, a light blocking layer BM, a cover panel C-PN, first and second adhesive layers AL1 and AL2, and an adhesive layer AL.

The input sensing part ISP, the anti-reflection layer RPL, the window WIN, and the light blocking layer BM may be disposed on the display panel DP. The cover panel C-PN may be disposed below the display panel DP.

In an embodiment, the display panel DP may include a display area DA and a non-display area NDA around the display area DA. The display area DA and the non-display area NDA may correspond to a display area DA and a non-display area NDA of FIG. 1, respectively.

According to an embodiment of the invention, the display panel 110 may be an emission-type display panel. In an embodiment, for example, the display panel DP may be an organic light emitting display panel or an inorganic light emitting display panel. An emission layer of the organic light emitting display panel may include an organic light emitting material. An emission layer of the inorganic light emitting display panel may include a quantum dot, a quantum rod, and the like. Hereinafter, for convenience of description, embodiments where the display panel DP is an organic light emitting display panel will be described.

The input sensing part ISP may be disposed on the display panel DP. The input sensing part ISP may include a plurality of sensing parts (not shown) that sense an external input in a capacitive manner. The input sensing part ISP may be manufactured directly on the display panel DP when the display device DD is manufactured. However, the embodiment of the invention is not limited thereto, and the input sensing part ISP may be provided as a panel that is separated from the display panel DP and may be attached to the display panel DP by an adhesion layer.

The anti-reflection layer RPL may be disposed on the input sensing part ISP. The anti-reflection layer RPL may be defined as an external light anti-reflection film. When the external light traveling toward the display panel DP is reflected from the display panel DP and provided again to an external user, the user may visually recognize the external light, like a mirror. In an embodiment, the anti-reflection layer RPL reduces reflectance of external light incident from an upper side of the display device DD toward the display panel DP, such that the external light may not be visible to a user.

For example, the anti-reflection layer RPL may include a phase retarder and/or a polarizer. However, the embodiment of the invention is not limited thereto, and the anti-reflection layer RPL may include a plurality of color filters that display the same color as pixels of the display panel DP. The color filters may filter external light to display the same color as that of the pixels. In this case, the external light may not be visually recognized by the user.

The window WIN may be disposed on the anti-reflection layer RPL. The window WIN may protect the display panel DP, the input sensing part ISP, and the anti-reflection layer RPL against external scratches and impacts.

The light blocking layer BM may be disposed on a bottom surface of the window WIN. The light blocking layer BM may be adjacent to an edge of the window WIN and may overlap the non-display area NDA when viewed on a plane or when viewed in the third direction DR3. The light blocking layer BM may be disposed in a groove GV defined in the bottom surface of the window WIN adjacent to the edge of the window WIN.

The cover panel C-PN may protect a lower portion of the display panel DP from external scratches. In addition, the cover panel C-PN may protect the display panel DP by absorbing an external shock applied to the display panel DP from a lower side of the display panel DP.

Although not shown, the cover panel C-PN may include a panel protective film disposed below the display panel DP to protect the lower portion of the display panel DP and a cushion layer disposed the panel protective film to absorb the external impact. The panel protective film may include a flexible plastic material such as polyethylene terephthalate (PET). The cushion layer may include a foam sheet having predetermined elastic force.

The first adhesive layer AL1 may be disposed between the input sensing part ISP and the anti-reflection layer RPL. The input sensing part ISP and the anti-reflective layer RPL may be bonded to each other by the first adhesive layer AL1.

The second adhesive layer AL2 may be disposed between the display panel DP and the cover panel C-PN. The display panel DP and the cover panel C-PN may be bonded to each other by the second adhesive layer AL2.

The adhesive layer AL may be disposed on the anti-reflection layer RPL, and the window WIN may be disposed on the adhesive layer AL. The adhesive layer AL may be disposed between the anti-reflection layer RPL and the window WIN to bond the anti-reflection layer RPL to the window WIN. The light blocking layer BM may be disposed between the adhesive layer AL and the window WIN.

Each of the adhesive layer AL and the first and second adhesive layers AL1 and AL6 may include a pressure sensitive adhesive (PSA) or an optically clear adhesive (OCA), but the type of adhesive is not limited thereto.

Widths of the window WIN, the anti-reflection layer RPL, and the adhesive layer AL may be greater than a width of the display panel DP. In this specification, the “width” may be defined as a value measured in a horizontal direction (e.g., the first direction DR1 or the second direction DR2). The window WIN, the anti-reflection layer RPL, and the adhesive layer AL may have a same width as each other.

An edge of the window WIN, an edge of the anti-reflection layer RPL, and an edge of the adhesive layer AL may be disposed outside the display panel DP when viewed on the plane or when viewed in the third direction DR3. That is, the edge of the window WIN, the edge of the anti-reflection layer RPL, and the edge of the adhesive layer AL may be disposed outwardly than a corresponding edge of the display panel DP. That is, when viewed on the plane or when viewed in the third direction DR3, the edge of the window WIN, the edge of the anti-reflection layer RPL, and the edge of the adhesive layer AL may protrude further than the corresponding edge of the display panel DP. When viewed on the plane or when viewed in the third direction DR3, the edge of the window WIN, the edge of the anti-reflection layer RPL, and the edge of the adhesive layer AL may overlap each other.

The widths of the window WIN, the anti-reflection layer RPL, and the adhesive layer AL may be greater than the widths of the input sensing part ISP, the cover panel C-PN, and the first and second adhesive layers AL1 and AL2. The edges of the window WIN, the anti-reflection layer RPL, and the adhesive layer AL may be disposed outside the edges of the input sensing part ISP, the cover panel C-PN, and the first and second adhesive layers AL1 and AL2.

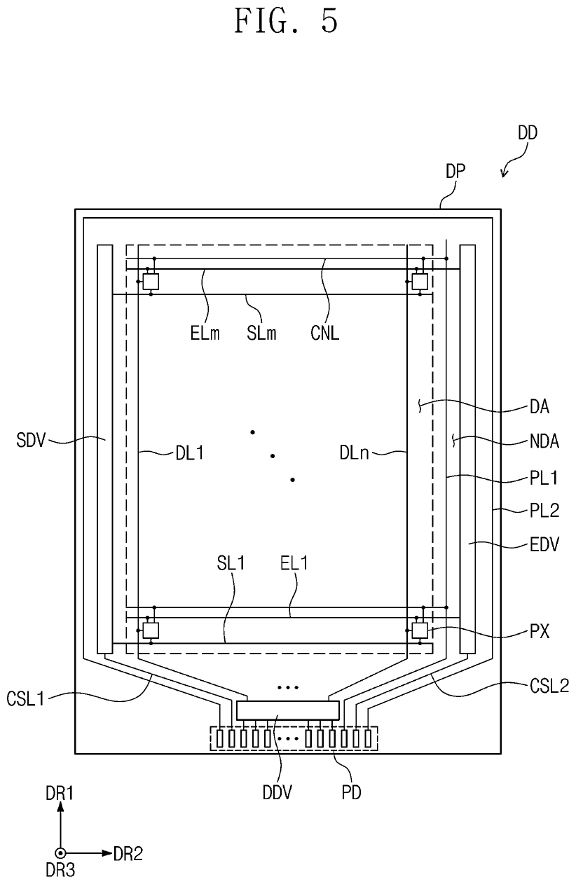

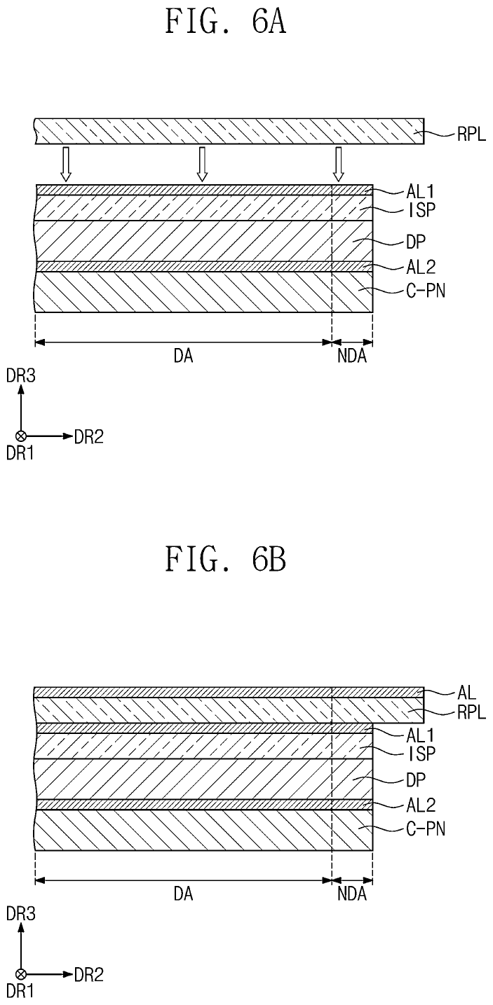

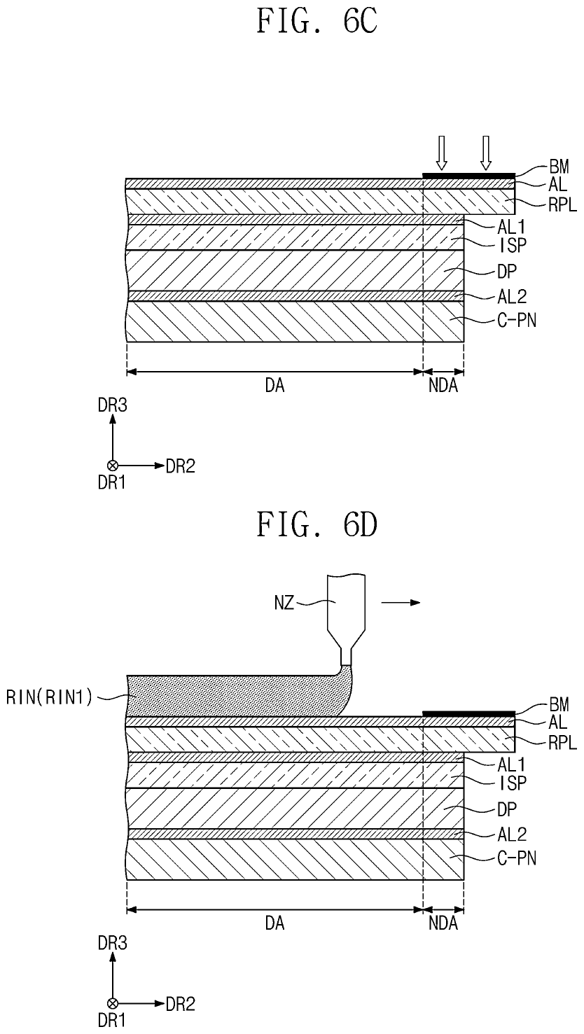

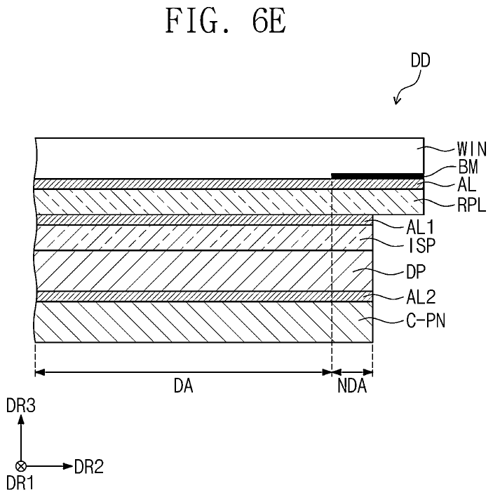

In an embodiment, the light blocking layer BM may be directly coated on the top surface of the adhesive layer AL. The window WIN may not be provided on the adhesive layer AL in the form of a film, but may be formed by coating a transparent resin directly on the top surface of the adhesive layer AL. The above-described constitutions will be described in detail with reference to FIGS. 6A and 6B.

FIG. 3 is a cross-sectional view illustrating an embodiment of the display panel illustrated in FIG. 2.

For example, FIG. 3 illustrates a cross-section of an embodiment of the display panel DP when viewed in the first direction DR1, and the input sensing part ISP is illustrated together with the display panel DP.

Referring to FIG. 3, an embodiment of the display panel DP may include a substrate SUB, a circuit element layer DP-CL, a display element layer DP-OLED, an encapsulation substrate EN-SB, a sealing layer SAL, and a filler FL. The circuit element layer DP-CL may be disposed on the substrate SUB. The display element layer DP-OLED may be disposed on the circuit element layer DP-CL.

A plurality of pixels may be disposed on the circuit element layer DP-CL and the display element layer DP-OLED. Each of the pixels may include a transistor disposed on the circuit element layer DP-CL and a light emitting element disposed on the display element layer DP-OLED and connected to the transistor.

The substrate SUB may include a display area DA and a non-display area NDA around the display area DA. The display element layer DP-OLED may be disposed on (or to overlap) the display area DA. An encapsulation substrate EN-SB may be disposed on the display device layer DP-OLED. In an embodiment, each of the substrate SUB and the encapsulation substrate EN-SB may be a rigid type. In such an embodiment, the display panel DP may be a rigid type.

A sealing layer SAL may be disposed between the substrate SUB and the encapsulation substrate EN-SB. The sealing layer SAL may be disposed on the non-display area NDA. The sealing layer SAL may bond the substrate SUB to the encapsulation substrate EN-SB. The display device layer DP-OLED may be sealed between the substrate SUB and the encapsulation substrate EN-SB by the sealing layer SAL. The sealing layer SAL may include a photocurable material.

The filler FL may be disposed between the substrate SUB and the encapsulation substrate EN-SB. The filler FL may be disposed in a space that is defined between the substrate SUB and the encapsulation substrate EN-SB and sealed by the sealing layer SAL. The filler FL may include a thermosetting material.

The input sensing part ISP may be directly disposed on the display panel DP. In an embodiment, for example, the input sensing part ISP may be disposed directly on the encapsulation substrate EN-SB.

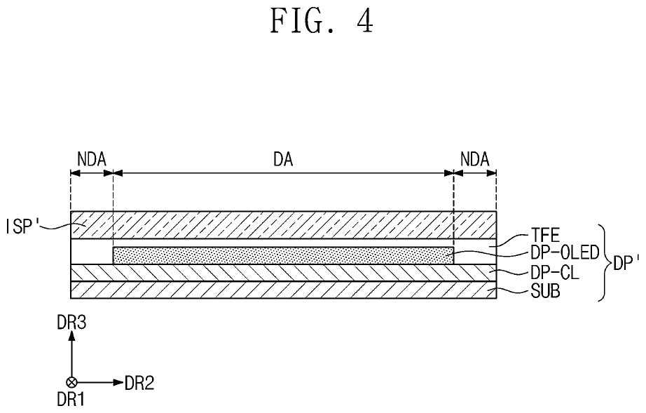

FIG. 4 is a cross-sectional view illustrating a display panel according to another embodiment of the invention.

For example, in FIG. 4, an input sensing part ISP′ is illustrated together with a display panel DP′.

Referring to FIG. 4, an embodiment of the display panel DP′ may include a circuit element layer DP-CL disposed on a substrate SUB, a display element layer DP-OLED disposed on the circuit element layer DP-CL, and a thin film encapsulation layer TFE disposed on the display element layer DP-OLED.

The display panel DP′ may be a flexible display panel. In an embodiment, for example, the substrate SUB may include a flexible plastic material such as polyimide. An arrangement structure of the circuit element layer DP-CL and the display element layer DP-OLED may be the same as that of the circuit element layer DP-CL and the display element layer DP-OLED illustrated in FIG. 3.

The thin film encapsulation layer TFE may be disposed on the circuit element layer DP-CL to cover the display element layer DP-OLED. The thin film encapsulation layer TEF may include inorganic layers and an organic layer between the inorganic layers. The inorganic layers may protect the pixels from moisture/oxygen. The organic layer may protect the pixels from foreign substances such as dust particles.

The input sensing part ISP′ may be directly disposed on the display panel DP′. In an embodiment, for example, the input sensing part ISP′ may be directly disposed on the thin film encapsulation layer TFE. The configuration of the input sensing part ISP′ may be substantially the same as the input sensing part ISP illustrated in FIG. 3.

FIG. 5 is a plan view of the display panel illustrated in FIG. 2.

Referring to FIG. 5, an embodiment of the display device DD may include a display panel DP, a scan driver SDV, a data driver DDV, a light emission driver EDV, and a plurality of first pads PD1.

In an embodiment, as shown in FIG. 5, the display panel DP may have a rectangular shape having long sides extending in the first direction DR1 and short sides extending in the second direction DR2, but the shape of the display panel DP is not limited thereto. The display panel DP may include a display area DA and a non-display area NDA surrounding the display area DA.

The display panel DP may include a plurality of pixels PX, a plurality of scan lines SL1 to SLm, a plurality of data lines DLI to DLn, a plurality of emission lines EL1 to ELm, first and second control lines CSL1 and CSL2, first and second power lines PL1 and PL2, and connection lines CNL. Here, m and n are natural numbers.

The pixels PX may be disposed on the display area DA. The scan driver SDV and the data driver DDV may be disposed on the non-display areas that are adjacent to the long sides of the display panel DP, respectively. The data driver DDV may be disposed on the non-display area NDA adjacent to one short side of the short sides of the display panel DP. When viewed on the plane or when viewed in the third direction DR3, the data driver DDV may be adjacent to a lower end of the display panel DP.

The scan lines SL1 to SLm may extend in the second direction DR2 and be connected to the pixels PX and the scan driver SDV. The data lines DLI to DLn may extend in the first direction DR1 and be connected to the pixels PX and the data driver DDV. The emission lines EL1 to ELm may extend in the second direction DR2 and be connected to the pixels PX and the light emission driver EDV.

The first power line PL1 may extend in the first direction DR1 and be disposed on the non-display area NDA. The first power line PL1 may be disposed between the display area DA and the light emission driver EDV.

The connection lines CNL may extend in the second direction DR2 and may be arranged in the first direction DR1 to be connected to the first power line PL1 and the pixels PX. The first voltage may be applied to the pixels PX through the first power line PL1 and the connection lines CNL, which are connected to each other.

The second power line PL2 may be disposed on the non-display area NDA to extend along the long sides of the display panel DP and another short side of the display panel DP on which the data driver DDV is not disposed. The second power line PL2 may be disposed outside the scan driver SDV and the light emission driver EDV.

Although not shown, the second power line PL2 may extend toward the display area DA and be connected to the pixels PX. A second voltage having a level less than that of the first voltage may be applied to the pixels PX through the second power line PL2.

The first control line CSL1 may be connected to the scan driver SDV, and the first control line CSL1 may extend toward the lower end of the display panel DP. The second control line CSL2 may be connected to the light emission driver EDV, and the second control line CSL2 may extend toward the lower end of the display panel DP. The data driver DDV may be disposed between the first control line CSL1 and the second control line CSL2.

The pads PD may be disposed on the non-display area NDA adjacent to a lower end of the display panel DP and may be closer to the lower end of the display panel DP than the data driver DDV. The data driver DDV, first and second power lines PL1 and PL2, and first and second control lines CSL1 and CSL2 may be connected to the pads PD. The data lines DLI to DLn may be connected to the data driver DDV, and the data drivers DDV may be connected to the pads PD, which correspond to the data lines DLI to DLn, respectively.

Although not shown, the display device DD may further include a timing controller to control operations of the scan driver SDV, the data driver DDV, and the light emission driver EDV and a voltage generator to generate first and second voltages. The timing controller and the voltage generator may be mounted on a printed circuit board and be connected to the pads PD through the printed circuit board.

The scan driver SDV may generate a plurality of scan signals, and the scan signals may be applied to the pixels PX through the scan lines SL1 to SLm. The data driver DDV may generate a plurality of data voltages, and the data voltages may be applied to the pixels PX through the data lines DLI to DLn. The light emission driver EDV may generate a plurality of emission signals, and the emission signals may be applied to the pixels PX through the emission lines EL1 to ELm.

The pixels PX may receive the data voltages in response to the scan signals. The pixels PX may emit light having luminance corresponding the data voltages in response to the emission signals to display an image.

FIGS. 6A to 6E are views for explaining a method for manufacturing a display device according to an embodiment of the invention.

For example, FIGS. 6A to 6E are enlarged views of a right side of the display device DD illustrated in FIG. 2.

Referring to FIG. 6A, in an embodiment of a method for manufacturing a display device, an anti-reflection layer RPL may be provided on the display panel DP. In an embodiment, for example, the anti-reflection layer RPL may be provided on the first adhesive layer AL1 on the input sensing part ISP. The anti-reflection layer RPL may be attached to the input sensing part ISP by the first adhesive layer AL1 and coupled to the input sensing part ISP.

In such an embodiment, as described above, the anti-reflection layer RPL may have a width greater than that of the display panel DP, and the edge of the anti-reflection layer RPL may be disposed outside the edge of the display panel DP. This reason will be described in detail below.

Referring to FIG. 6B, an adhesive layer AL having a same width as the anti-reflection layer RPL may be provided on the anti-reflection layer RPL. When viewed on the plane or when viewed in the third direction DR3, the adhesive layer AL may entirely overlap the anti-reflection layer RPL, that is, provided on an entire upper surface of the anti-reflection layer RPL. Thus, as described above, the edge of the adhesive layer AL may be disposed outside the edge of the display panel DP.

Referring to FIG. 6C, a light blocking layer BM may be provided on the adhesive layer AL. The light blocking layer BM may be adjacent to the edge of the adhesive layer AL and may overlap the non-display area NDA when viewed on the plane or when viewed in the third direction DR3. The light blocking layer BM may be formed by directly applying a black resin on the top surface of the adhesive layer AL and curing the applied resin.

Referring to FIG. 6D, the transparent resin RIN discharged from a nozzle NZ may be directly applied to the top surface of the adhesive layer AL. The transparent resin RIN may also be applied directly to the top surface of the light blocking layer BM. Hereinafter, the transparent resin RIN used in manufacturing the display device DD may be defined as a first transparent resin RIN1.

In an embodiment, for example, the first transparent resin RIN1 may include an epoxy resin. However, the embodiment of the invention is not limited thereto, and the first transparent resin RIN1 may include at least one selected from various resins which are transparent.

Referring to FIGS. 6D and 6E, the first transparent resin RIN1 applied directly to the top surface of the adhesive layer AL may be cured to form a window WIN. That is, the window WIN may be formed by directly coating the first transparent resin RIN1 on the top surface of the adhesive layer AL. This process may be defined as a coating process. In such an embodiment, the window WIN may be defined by a transparent resin coating layer, which is coated the top surface of the adhesive layer AL. Since the first transparent resin RIN1 is entirely applied on the anti-reflection layer RPL, the edge of the window WIN may be disposed outside the edge of the display panel DP.

The window WIN may have a width greater than that of each of the input sensing part ISP and the display panel DP to sufficiently protect the input sensing part ISP and the display panel DP and also may be desired to cover the entire input sensing part ISP and display panel DP. Thus, the window WIN may be provided to have a width greater than that of each of the input sensing part ISP and the display panel DP, and thus, the edge of the window WIN may be disposed outside the edges of the input sensing part ISP and the display panel DP.

An area for applying the first transparent resin RIN1 having fluidity (i.e., an area on which the first transparent resin RIN1 is to be applied) may be defined by the anti-reflection layer RPL. For example, in order for the window WIN to be formed to have a width greater than that of the display panel DP, the first transparent resin RIN1 has to be applied to an area greater than that of the display panel DP. That is, in such an embodiment, a structure having an area greater than that of the display panel DP and supporting the first transparent resin RIN1 may be provided.

The anti-reflection layer RPL may have a width greater than that of the display panel DP and be provided on the display panel DP to define an area for applying the first transparent resin RIN1. The first transparent resin RIN1 may be provided on the anti-reflection layer RPL having a width greater than that of the display panel DP and may be supported by the anti-reflection layer RPL. Thus, the first transparent resin RIN1 may be applied to an area greater than that of the display panel DP.

The adhesive layer AL may also be supported by the anti-reflection layer RPL and provided on the anti-reflection layer RPL to entirely overlap the anti-reflection layer RPL. Thus, the adhesive layer AL may also be provided on the anti-reflection layer RPL to have a width greater than that of the display panel DP.

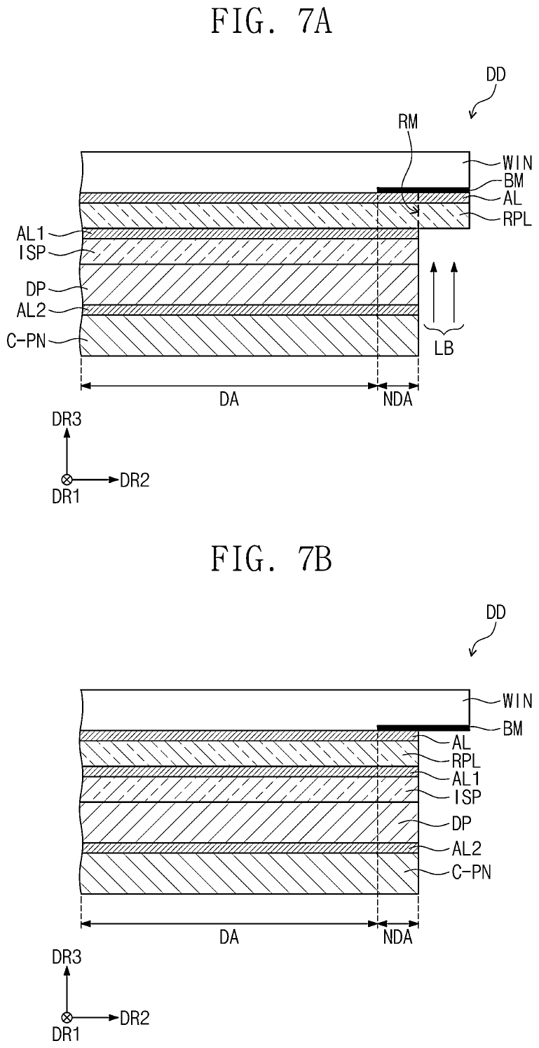

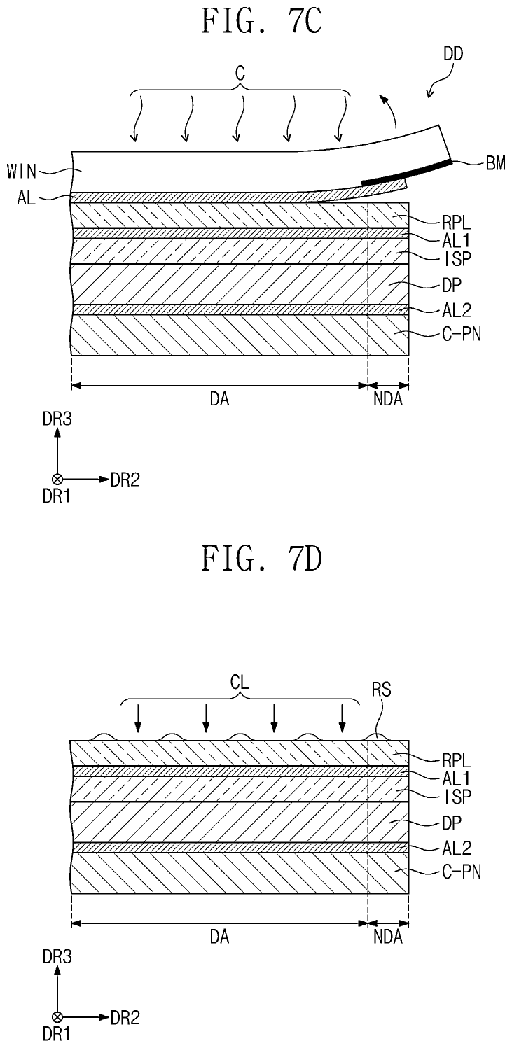

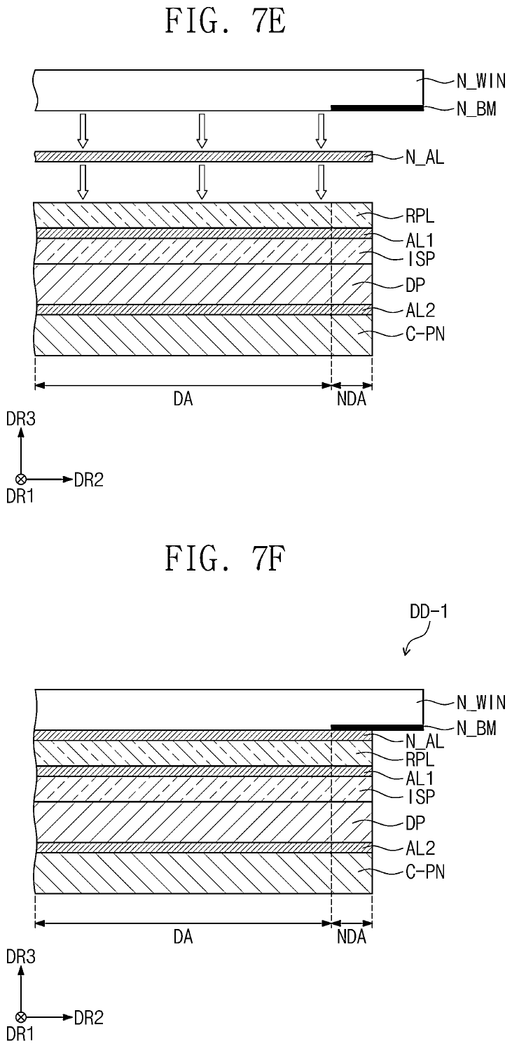

FIGS. 7A to 7F are views for explaining a method for repairing the display device according to an embodiment of the invention.

For example, FIGS. 7A to 7F illustrate cross-sections corresponding to FIGS. 6A to 6E.

Referring to FIG. 7A, in an embodiment of a method for repairing a display device DD, the display device DD may be prepared. The display device DD may be a defective display device DD to be repaired, and the window WIN may be defective. For example, in a case where a scratch or a crack occurs in the window WIN, a process of replacing the window WIN in the display device DD may be desired to be performed. The repair process for the display device DD may be defined as a rework process.

A portion of the anti-reflection layer RPL disposed outside the display panel DP and a portion of the adhesive layer AL disposed outside the display panel DP may be defined as a removal portion RM.

Referring to FIGS. 7A and 7B, a laser beam LB may be radiated toward the removal portion RM. The removal portion RM may be removed by the laser beam LB. The laser beam LB may be radiated from a lower side of the removal unit RM toward the removal portion RM. Although not shown, a laser for generating the laser beam LB may be disposed below the removal portion RM.

The removal process of the removal part RM may be performed before the removal process of the window WIN and the adhesive layer AL, which will be described below with reference to FIG. 7C. As the removal portion RM is removed, in the repair process, the anti-reflection layer RPL and the adhesive layer AL may be deformed to have a same width as the display panel DP. Thus, the anti-reflection layer RPL and the adhesive layer AL may not extend outward beyond the display panel DP when viewed on the plane or when viewed in the third direction DR3.

When a portion of the adhesive layer AL disposed outside the display panel DP is removed, a portion of the light blocking layer BM disposed outside the display panel DP may be exposed to the outside. For example, a lower portion of the light blocking layer BM disposed outside the display panel DP may be exposed to the outside.

Referring to FIG. 7C, when the window WIN and the adhesive layer AL are removed, the display device DD may be cooled. In an embodiment, for example, cold air C is supplied to the display device DD by a cooling device (not shown), such that the display device DD may be cooled to a temperature below zero. In an embodiment, for example, the subzero temperatures may be less than about 0 degrees Celsius and greater than or equal to about-200 degrees Celsius. An adhesive strength of the adhesive layer AL may be reduced at the subzero temperature.

The window WIN, the light blocking layer BM, and the adhesive layer AL may be removed from the display device DD. The window WIN may be removed starting from the edge of the window WIN that protrudes beyond the display panel DP. The above-mentioned removal part RM may be removed, and thus, only the edge of the window WIN may protrude to the outside.

An outer edge of the window WIN may be easily gripped by a grip device (not shown), and thus, the window WIN may be removed from the display device DD. In such an embodiment, the removal portion RM may be removed, and the anti-reflection layer RPL may not protrude to the outside of the display panel DP since the anti-reflection layer RPL is not to be removed.

The bonding force between the window WIN directly coated on the adhesive layer AL and the adhesive layer AL may be greater than the bonding force between the anti-reflection layer RPL and the adhesive layer AL. In addition, since the adhesive strength of the adhesive layer AL decreases at the subzero temperature, the bonding strength of the adhesive layer AL to the anti-reflection layer RPL may decrease. Thus, when the window WIN is removed, the adhesive layer AL, which is more strongly bonded to the window WIN, may be separated from the anti-reflection layer RPL and removed together with the window WIN.

Referring to FIG. 7D, after the window WIN and the adhesive layer AL are removed, a residue RS of the adhesive layer AL may remain on the anti-reflection layer RPL. The residue RS of the adhesive layer AL may be removed by a cleaning liquid CL. In an embodiment, for example, the cleaning liquid CL may include ethanol, but is not limited thereto and may include various substances.

Referring to FIG. 7E, a new adhesive layer N_AL may be provided on the anti-reflection layer RPL, and a new window N_WIN may be provided on the new adhesive layer N_AL. The new adhesive layer N_AL has a same width as the display panel DP and may entirely overlap the display panel DP when viewed on the plane when viewed in the third direction DR3. The new window N_WIN may have a width greater than the display panel DP, and an edge of the new window N_WIN may be disposed outside the display panel DP.

The new adhesive layer N_AL may include or be made of a same material as the adhesive layer AL described above. The new window N_WIN may be manufactured in the form of a film and provided on the anti-reflection layer RPL. The above-described window WIN may be formed by applying the first transparent resin RIN1 on the top surface of the adhesive layer AL, but the new window N_WIN may be provided in the form of a film on the new adhesive layer N_AL.

A new light blocking layer N_BM may be disposed on a bottom surface of the new window N_WIN. The new light blocking layer N_BM may be directly coated on the bottom surface of the new window N_WIN. The new light blocking layer N_BM may include or be made of a same material as the light blocking layer BM described above. The position of the new light blocking layer N_BM may be the same as the light blocking layer BM described above.

Referring to FIG. 7F, the new window N_WIN and the new light blocking layer N_BM may be attached to the anti-reflection layer RPL by the new adhesive layer N_AL. According to this repair process, a reworked display device DD-1 may be manufactured.

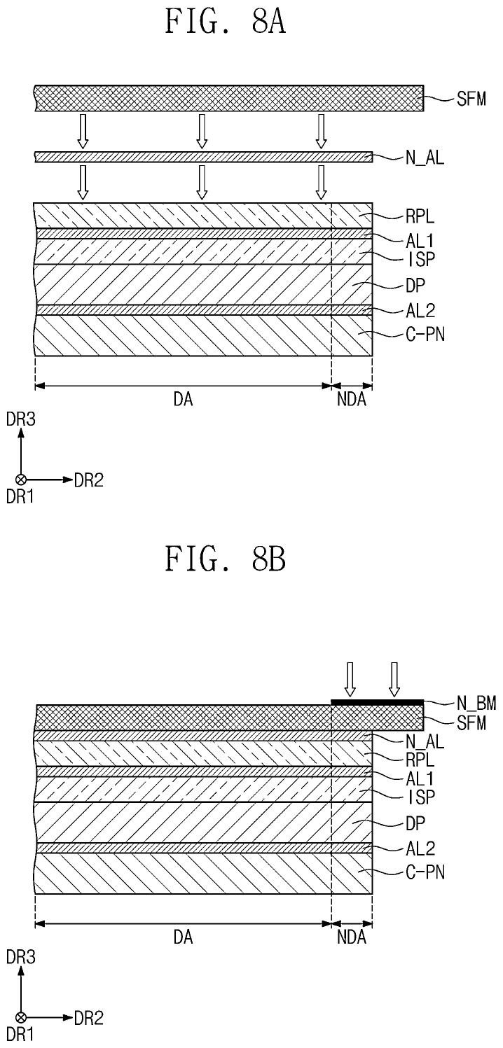

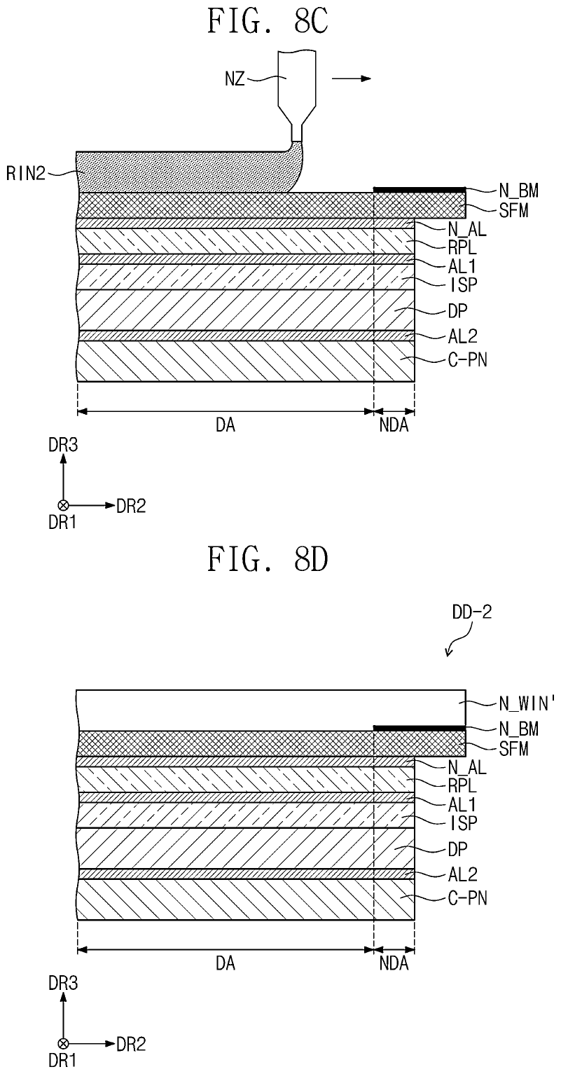

FIGS. 8A to 8D are views for explaining a method for repairing a display device according to another embodiment of the invention.

For example, FIGS. 8A to 8D illustrate cross-sections corresponding to FIGS. 6A to 6E.

In the method for repairing the display device DD according to another embodiment of the invention, a process of removing the window WIN, the light blocking layer BM, and the adhesive layer AL may be the same as those of the above-described method for repairing the display device illustrated in FIGS. 7A to 7D. Thus, in FIG. 8A, the cross-sectional structure corresponding to FIG. 7E is illustrated, in which the anti-reflection layer RPL from which the removal portion RM is removed and the display panel DP below the anti-reflection layer RPL are illustrated.

Referring to FIG. 8A, a new adhesive layer N_AL may be provided on the anti-reflection layer RPL, and a support film SFM may be provided on the new adhesive layer N_AL. In an embodiment, for example, the support film SFM may include a plastic material such as polyethyleneterephthalate (PET).

The new adhesive layer N_AL may have a same configuration as the new adhesive layer N_AL illustrated in FIG. 7E. The support film SFM may have a width greater than that of the display panel DP. An edge of the support film SFM may be disposed outside the edge of the display panel DP. The edge of the support film SFM may be disposed outside an edge of the new adhesive layer N_AL.

Referring to FIG. 8B, the support film SFM may be attached to the anti-reflection layer RPL by the new adhesive layer N_AL. A new light blocking layer N_BM may be provided on the support film SFM. The new light blocking layer N_BM may be directly coated on the top surface of the support film SFM. The new light blocking layer N_BM may have the same configuration as the new light blocking layer N_BM illustrated in FIG. 7E.

Referring to FIG. 8C, a second transparent resin RIN2 discharged from a nozzle NZ may be directly applied to the top surface of the support film SFM. The second transparent resin RIN2 may be directly applied to the top surface of the light blocking layer BM. The second transparent resin RIN2 may include a same material as the first transparent resin RIN1.

Referring to FIGS. 8C and 8D, the second transparent resin RIN2 may be cured to form a new window N_WIN′. That is, the new window N_WIN′ may be formed by directly coating the second transparent resin RIN2 on the top surface of the support film SFM. Since the second transparent resin RIN2 is entirely applied on the support film SFM, an edge of the new window N_WIN′ may be disposed outside the edge of the display panel DP.

An area for applying the second transparent resin RIN2 having fluidity may be defined by the support film SFM. The support film SFM may have a width greater than that of the display panel DP and may be provided on the display panel DP to define an area for applying the second transparent resin RIN2.

The second transparent resin RIN2 may be provided on the support film SFM having a width greater than that of the display panel DP and may be supported by the support film SFM. Thus, the second transparent resin RIN2 may be applied to an area greater than that of the display panel DP.

As a result, a new window N_WIN′ having a width greater than that of the display panel DP may be provided. According to this repair process, a reworked display device DD-2 may be manufactured.

Referring to FIGS. 8A to 8D, similar to FIGS. 7E and 7F, a new adhesive layer N_AL may be provided on the anti-reflection layer RPL, and a new window N_WIN′ may be provided on the new adhesive layer N_AL. However, unlike FIGS. 7E and 7F, in the process illustrated in FIGS. 8A to 8D, an area on which the second transparent resin RIN2 is provided may be defined for the new window N_WIN′ provided through the coating process, and thus, a support film SFM for supporting the second transparent resin RIN2 may be used.

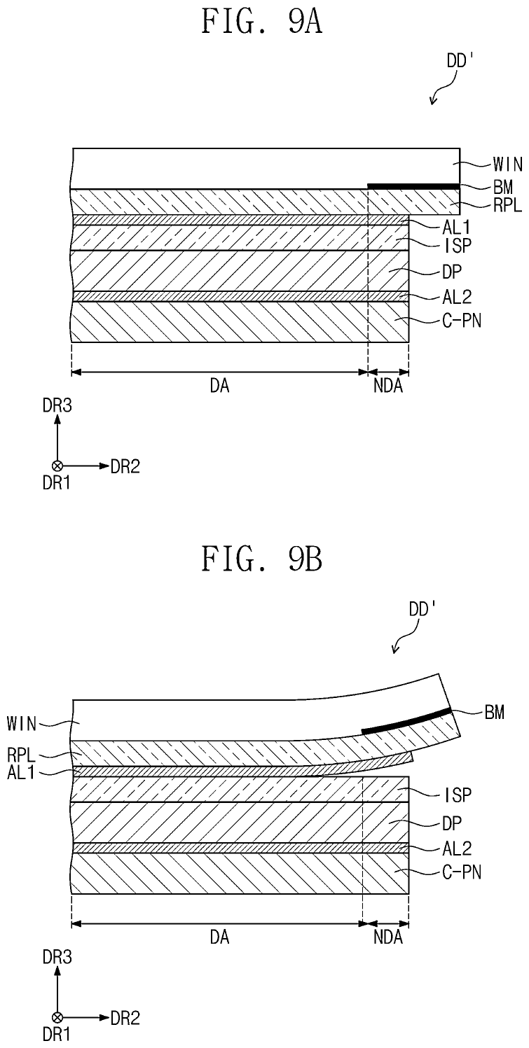

FIGS. 9A and 9B are views for explaining a process of removing a window of a comparative display device.

Referring to FIG. 9A, a comparative display device DD′ may not include the adhesive layer AL described above. The window WIN may be directly coated on the top surface of the anti-reflection layer RPL through the coating process illustrated in FIGS. 6D and 6E. The bonding force between the window WIN directly coated on the anti-reflection layer RPL and the anti-reflection layer RPL may be greater than the bonding force between the anti-reflection layer RPL and the first adhesive layer AL1.

Referring to FIG. 9B, when the window WIN is defective, only the window WIN may be desired to be removed. However, even the anti-reflection layer RPL, which is more strongly bonded to the window WIN, may be removed from a display device DD′ together with the window WIN. Thus, even the normal anti-reflection layer RPL, which is not defective, may be removed.

In an embodiment of the disclosure, as described above referring to FIGS. 7A to 8D, the adhesive layer AL may be disposed between the window WIN and the anti-reflection layer RPL, and thus, the window WIN may not be directly coated on the anti-reflection layer RPL. Thus, the adhesive layer AL and the window WIN may be easily removed from the display device DD. In addition, during the repair process, since only the window WIN protrudes outside the display panel DP, the window WIN may be easily gripped and removed.

Thus, the display device DD may be easily repaired using the method for repairing the display device DD according to an embodiment of the invention.

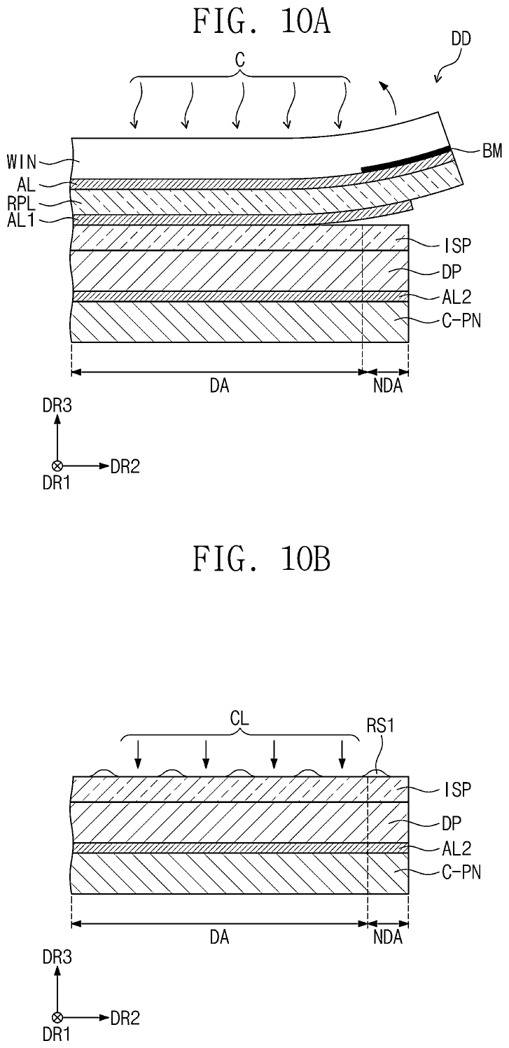

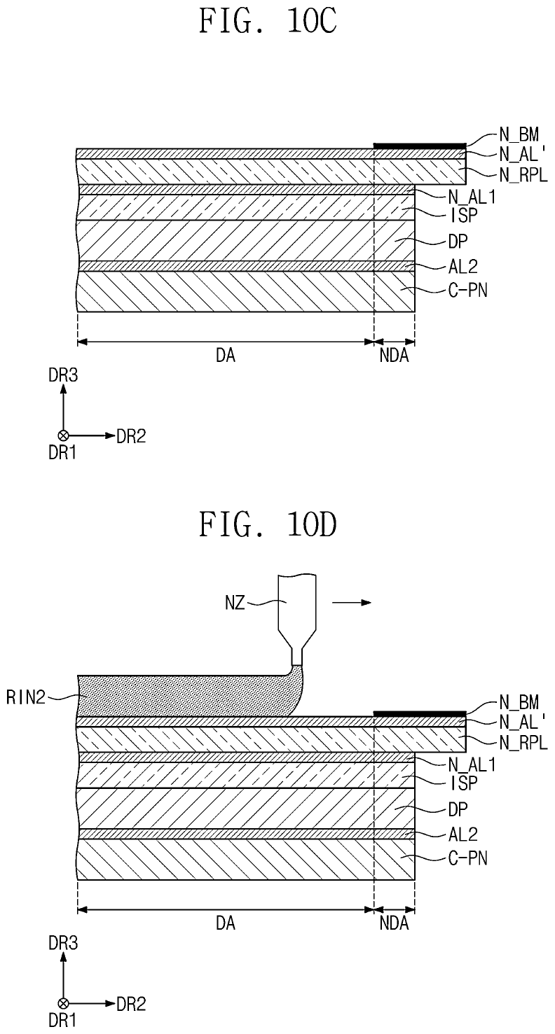

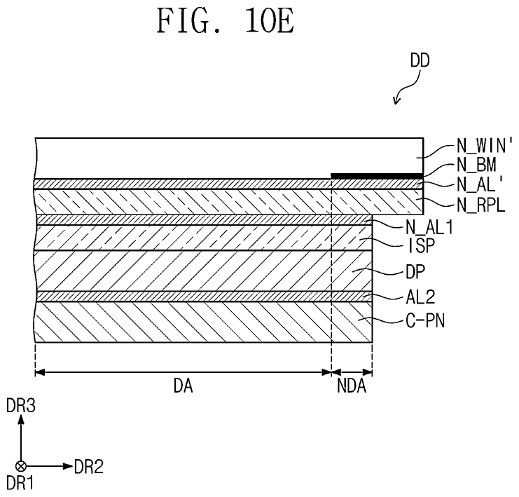

FIGS. 10A to 10E are views for explaining a method for repairing a display device according to another embodiment of the invention.

For example, FIGS. 10A to 10E illustrate cross-sections corresponding to FIGS. 6A to 6E. Hereinafter, the repair method illustrated in FIGS. 10A to 10E will be described, focusing on methods different from the repair method illustrated in FIGS. 7A to 8D.

Referring to FIG. 10A, in an embodiment of explaining a method for repairing a display device DD, the display device DD may be prepared. The display device DD may be a defective display device DD desired to be repaired, and the window WIN and anti-reflection layer RPL may be defective.

Since cold air C is supplied to the display device DD by a cooling device (not shown), the display device DD may be cooled to a temperature below zero. An adhesive strength of the first adhesive layer AL1 may be reduced at the subzero temperature.

The edge of the window WIN and the edge of the anti-reflection layer RPL, which protrude to the outside, may be easily gripped by a grip device (not shown), and thus, the window WIN and the anti-reflection layer RPL may be removed from the display device DD. In addition, the light blocking layer BM, the adhesive layer AL, and the first adhesive layer AL1 may be removed together with the window WIN and the anti-reflection layer RPL.

Referring to FIG. 10B, residue RS1 of the first adhesive layer AL1 may remain on the input sensing part ISP. The residue RS1 of the first adhesive layer AL1 may be removed using a cleaning liquid CL.

Referring to FIG. 10C, a first new adhesive layer N_AL1 may be provided on the input sensing part ISP, and a new anti-reflection layer N_RPL may be provided on the first new adhesive layer N_AL1. That is, after the defective anti-reflection layer RPL is removed, a new anti-reflection layer N_RPL may be provided on the display panel DP.

The new anti-reflection layer N_RPL may have substantially the same configuration as the anti-reflection layer RPL illustrated in FIG. 6C. Thus, the new anti-reflection layer N_RPL may have a width greater than that of the display panel DP, and the edge of the new anti-reflection layer N_RPL may be disposed outside the edge of the display panel DP.

A new adhesive layer N_AL′ may be provided on the new anti-reflection layer N_RPL, and a new light blocking layer N_BM may be provided on the new adhesive layer N_AL′. The new adhesive layer N_AL′ may have a same configuration as the adhesive layer AL illustrated in FIG. 6C.

Referring to FIGS. 10D and 10E, the second transparent resin RIN2 may be directly applied to a top surface of the new adhesive layer N_AL′. The second transparent resin RIN2 may be directly applied to a top surface of the new light blocking layer N_BM.

The second transparent resin RIN2 may be cured to form a new window N_WIN′. That is, the new window N_WIN′ may be formed by directly coating the second transparent resin RIN2 on a top surface of the new adhesive layer N_AL′. The new window N_WIN′ may have the same configuration as the window WIN illustrated in FIG. 7E.

An area for applying the second transparent resin RIN2 having fluidity may be defined by the new anti-reflection layer N_RPL. The second transparent resin RIN2 may be provided on the new anti-reflection layer N_RPL having a width greater than that of the display panel DP and supported by the new anti-reflection layer N_RPL. Thus, the second transparent resin RIN2 may be applied to an area greater than that of the display panel DP.

As a result, a new window N_WIN′ having a width greater than that of the display panel DP may be provided. According to this repair process, a reworked display device DD-3 may be manufactured.

According to the embodiments of the invention, the adhesive layer may be disposed on the anti-reflection layer on the display panel, the window may be disposed on the adhesive layer, and the window may be directly coated on the top surface of the adhesive layer. The window may be more easily separated when the window is directly coated on the top surface of the adhesive layer than when the window is directly coated on the top surface of the anti-reflection layer. As a result, the display device may be repaired more easily.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A method for repairing a display device, the method comprising:
preparing a display device comprising a display panel, an anti-reflection layer disposed on the display panel, an adhesive layer disposed on the anti-reflection layer, and a window disposed on the adhesive layer, wherein an edge of the window is disposed outside the display panel when viewed in a thickness direction of the display panel;
removing the window and the adhesive layer from the display device;
providing a new adhesive layer on the anti-reflection layer; and
providing a new window on the new adhesive layer,
wherein the window is formed by directly coating a first transparent resin on a top surface of the adhesive layer.

2. The method of claim 1, wherein the window is removed starting from an edge of the window.

3. The method of claim 1, further comprising cooling the display device at a temperature below zero when the window and the adhesive layer are removed from the display device.

4. The method of claim 3, wherein the temperature below zero is less than about 0 degrees Celsius and greater than or equal to about-200 degrees Celsius.

5. The method of claim 1, wherein an edge of the adhesive layer and an edge of the anti-reflection layer are disposed outside the display panel when viewed in the thickness direction of the display panel.

6. The method of claim 5, wherein the display panel comprises a display area and a non-display area around the display area, and
the display device further comprises a light blocking layer disposed between the adhesive layer and the window and adjacent of the edge of the window,
wherein the light blocking layer overlaps the non-display area.

7. The method of claim 6, further comprising removing a portion of the anti-reflection layer and a portion of the adhesive layer, which are disposed outside the display panel, before the removing the window and the adhesive layer from the display device.

8. The method of claim 7, wherein the portion of the anti-reflection layer and the portion of the adhesive layer are removed by a laser beam.

9. The method of claim 7, wherein, when the portion of the adhesive layer is removed, a lower portion of the light blocking layer disposed outside the display panel is exposed to an outside.

10. The method of claim 1, further comprising removing a residue of the adhesive layer, which remains on the anti-reflection layer, after the removing the window and the adhesive layer.

11. The method of claim 10, wherein the residual of the adhesive layer is removed by a cleaning liquid.

12. The method of claim 1, wherein the new window is in a form of a film.

13. The method of claim 1, further comprising providing a support film on the new adhesive layer,
wherein the new window is disposed on the support film, and
an edge of the support film is disposed outside the display panel when viewed in the thickness direction of the display panel.

14. The method of claim 13, wherein the new window is formed by directly coating a second transparent resin on a top surface of the support film.

15. The method of claim 1, further comprising:
removing the anti-reflection layer; and
providing a new anti-reflection layer on the display panel,
wherein the new adhesive layer is disposed on the new anti-reflection layer, and
an edge of the new anti-reflection layer is disposed outside the display panel when viewed in the thickness direction of the display panel.

16. The method of claim 15, wherein the new window is formed by directly coating a second transparent resin on a top surface of the new adhesive layer.

17. A display device comprising:
a display panel;
an anti-reflection layer disposed on the display panel;
an adhesive layer disposed on the anti-reflection layer; and
a window disposed on the adhesive layer,
wherein each of the window, the adhesive layer, and the anti-reflection layer has a width greater than a width of the display panel when viewed in a thickness direction of the display panel, and
the window is defined by a transparent resin coating layer which is directly coated on a top surface of the adhesive layer.

18. The display device of claim 17, wherein the window, the adhesive layer, and the anti-reflection layer have a same width as each other,
an edge of the window, an edge of the adhesive layer, and an edge of the anti-reflection layer overlap each other when viewed in the thickness direction of the display panel, and
the edge of the window, the edge of the adhesive layer, and the edge of the anti-reflection layer are disposed outside the display panel when viewed in the thickness direction of the display panel.

19. A method for manufacturing a display device, the method comprising:
providing an anti-reflection layer on a display panel;
providing an adhesive layer on the anti-reflection layer;
directly applying a transparent resin on a top surface of the adhesive layer; and
curing the transparent resin to form a window,
wherein each of the window, the adhesive layer, and the anti-reflection layer has a width greater than a width of the display panel when viewed in a thickness direction of the display panel.

20. The method of claim 19, wherein the window, the adhesive layer, and the anti-reflection layer have a same width as each other,
an edge of the window, an edge of the adhesive layer, and an edge of the anti-reflection layer overlap each other when viewed in the thickness direction of the display panel, and
the edge of the window, the edge of the adhesive layer, and the edge of the anti-reflection layer are disposed outside the display panel when viewed in the thickness direction of the display panel.
